(19) United States
(12) Patent Application Publication
(10) Pub. No.: US 2025/0366288 A1
(43) Pub. Date: Nov. 27, 2025

(54) DISPLAY APPARATUS,METHOD OF MANUFACTURING DISPLAY APPARATUS, AND ELECTRONIC DEVICE INCLUDING DISPLAY APPARATUS

(71) Applicant: Samsung Display Co., LTD., Yongin-si (KR)

(72) Inventors: Sunghoon LIM, Yongin-si (KR); Donghan KANG, Yongin-si (KR); Kyumin KIM, Yongin-si (KR); Jeonghwan KIM, Yongin-si (KR); Jeehoon KIM, Yongin-si (KR); Jaecheol PARK, Yongin-si (KR); Keunchan OH, Yongin-si (KR); Gakseok LEE, Yongin-si (KR); Woogeun LEE, Yongin-si (KR); Sunkyu JOO, Yongin-si (KR)

(21) Appl. No.: 19/031,644

(22) Filed: Jan. 18, 2025

(30) Foreign Application Priority Data
May 23, 2024 (KR) 10-2024-0067259

(51) Int. Cl. H10H 29/37; H10H 29/01; H10H 29/14; H10H 29/80

(52) U.S. Cl. CPC H10H 29/37; H10H 29/012; H10H 29/142; H10H 29/842

(57) ABSTRACT

The display apparatus includes: a substrate, a first subpixel electrode and a second subpixel electrode that are spaced apart from each other on the substrate, a pixel definition layer disposed on the first subpixel electrode and the second subpixel electrode and defining a first opening overlapping the first subpixel electrode and a second opening overlapping the second subpixel electrode, and a first barrier located on the pixel definition layer between the first opening and the second opening, wherein the first barrier extends in a first direction, and a length of the first barrier in the first direction is greater than each of a length of the first opening in the first direction and a length of the second opening in the first direction, and an angle formed between one lateral surface of the first barrier and a top surface of the pixel definition layer is less than 90 degrees.

This application claims priority to Korean Patent Application No. 10-2024-0067259, filed on May 23, 2024, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same, and more particularly, to a display apparatus including a light-emitting diode and a method of manufacturing the display apparatus. One or more embodiments relate to an electronic device including the display apparatus.

### 2. Description of the Related Art

An electronic device may include a display apparatus configured to display an image. Subpixels constituting the display apparatus may include a light-emitting diode at a lower end and a color element at an upper end. The color element may include quantum dots corresponding to color of light to be emitted. The color element may include a color filter corresponding to color of light to be emitted.

### SUMMARY

Some of light emitted from a light-emitting diode (e.g., front light) may be directed toward a corresponding color element, while other some of the light (e.g., side light or planar light) may be directed toward an adjacent light-emitting diode or toward an adjacent color element. Light directed toward an adjacent light-emitting diode or an adjacent color element may degrade color gamut of a display apparatus. This phenomenon may be further revealed as a distance between adjacent light-emitting diodes decreases, i.e., as the resolution of the display apparatus increases. One or more embodiments include a display apparatus and a method of manufacturing the same for resolving various problems including the above problem.

Additional aspects will be set forth in part in the description which follows and, in part, will be apparent from the description, or may be learned by practice of the presented embodiments of the disclosure.

According to one or more embodiments, a display apparatus includes a substrate, a first subpixel electrode and a second subpixel electrode that are spaced apart from each other on the substrate, a pixel definition layer disposed on the first subpixel electrode and the second subpixel electrode and defining a first opening overlapping the first subpixel electrode and a second opening overlapping the second subpixel electrode, and a first barrier located on the pixel definition layer between the first opening and the second opening, where the first barrier extends in a first direction, and a length of the first barrier in the first direction is greater than each of a length of the first opening in the first direction and a length of the second opening in the first direction, and an angle formed between one lateral surface of the first barrier and a top surface of the pixel definition layer is less than 90 degrees.

According to an embodiment, the first barrier may include a light-shielding material.

According to an embodiment, a width of the first barrier in a second direction perpendicular to the first direction may be less than a distance between a first edge of the pixel definition layer defining the first opening and a second edge of the pixel definition layer defining the second opening in the second direction.

According to an embodiment, a width of the first barrier in the second direction may be equal to a distance between one edge of the first subpixel electrode and one edge of the second subpixel electrode, which are adjacent to each other in the second direction.

According to an embodiment, the angle formed between one lateral surface of the first barrier and a top surface of the pixel definition layer may be greater than 30 degrees.

According to an embodiment, a length of the first opening in the first direction may be greater than a width of the first opening in a second direction perpendicular to the first direction.

According to an embodiment, the display apparatus may further include a third subpixel electrode spaced apart from the first subpixel electrode and the second subpixel electrode on the substrate, and a second barrier disposed on the pixel definition layer and extending in the first direction, where the pixel definition layer defines a third opening overlapping the third subpixel electrode, and the second barrier is located between the second opening and the third opening.

According to an embodiment, a length of the second barrier in the first direction may be greater than a length of the third opening in the first direction.

According to an embodiment, a length of the first barrier in the first direction may be greater than a length of the second opening in the first direction.

According to an embodiment, the display apparatus may further include an encapsulation layer disposed on the pixel definition layer and the first barrier, where a distance from the top surface of the pixel definition layer to a top surface of the encapsulation layer may be greater than a distance from a top surface of the pixel definition layer to a top surface of the first barrier.

According to one or more embodiments, a method of manufacturing a display apparatus includes: disposing a first subpixel electrode and a second subpixel electrode on a substrate to be spaced apart from each other, disposing a pixel definition layer defining a first opening overlapping the first subpixel electrode and a second opening overlapping the second subpixel electrode on the first subpixel electrode and the second subpixel electrode, respectively, and locating a first barrier on the pixel definition layer between the first opening and the second opening, where the first barrier extends in a first direction, and a length of the first barrier in the first direction is greater than each of a length of the first opening in the first direction and a length of the second opening in the first direction, and an angle formed between one lateral surface of the first barrier and a top surface of the pixel definition layer is less than 90 degrees.

According to an embodiment, the first barrier may include a light-shielding material.

According to an embodiment, a width of the first barrier in a second direction perpendicular to the first direction may be less than a distance between a first edge of the pixel definition layer defining the first opening and a second edge of the pixel definition layer defining the second opening in the second direction.

According to an embodiment, a width of the first barrier in the second direction may be equal to a distance between one edge of the first subpixel electrode and one edge of the second subpixel electrode, which are adjacent to each other in the second direction.

According to an embodiment, the angle formed between one lateral surface of the first barrier and a top surface of the pixel definition layer may be greater than 30 degrees.

According to an embodiment, a length of the first barrier in the first direction may be greater than a width of the first opening in the second direction perpendicular to the first direction.

According to an embodiment, the method may further include locating a third subpixel electrode to be spaced apart from the first subpixel electrode and the second subpixel electrode on the substrate, and locating a second barrier extending in the first direction on the pixel definition layer, where the pixel definition layer defines a third opening overlapping the third subpixel electrode, and the second barrier is located between the second opening and the third opening.

According to an embodiment, a length of the second barrier in the first direction may be greater than a length of the third opening in the first direction.

According to an embodiment, a length of the first barrier in the first direction may be greater than a length of the second opening in the first direction.

According to one or more embodiments, an electronic device includes a display apparatus, wherein the display apparatus includes a substrate, a first subpixel electrode and a second subpixel electrode that are spaced apart from each other on the substrate, a pixel definition layer disposed on the first subpixel electrode and the second subpixel electrode and defining a first opening overlapping the first subpixel electrode and a second opening overlapping the second subpixel electrode, and a first barrier located on the pixel definition layer between the first opening and the second opening, where the first barrier extends in a first direction, and a length of the first barrier in the first direction is greater than each of a length of the first opening in the first direction and a length of the second opening in the first direction, and an angle formed between one lateral surface of the first barrier and a top surface of the pixel definition layer is less than 90 degrees.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a display apparatus according to an embodiment;

FIG. 2 is a cross-sectional view of a portion of a display apparatus according to an embodiment;

FIG. 3 is an enlarged plan view of a portion of a display apparatus according to an embodiment;

FIG. 4 is a cross-sectional view showing a portion of a display apparatus according to an embodiment;

FIG. 5 is an enlarged cross-sectional view of a portion of a display apparatus according to an embodiment;

FIG. 6 is an enlarged cross-sectional view of a portion of a display apparatus according to an embodiment; and

FIGS. 7A, 7B, 7C, 7D, 7E, 7F, and 7G are schematic cross-sectional views showing operations in a manufacturing process of a display apparatus according to an embodiment.

FIG. 8 is a block diagram of an electronic device according to an embodiment.

FIG. 9 is a schematic diagram of electronic devices according to several embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating embodiments are referred to gain a sufficient understanding of embodiments, the merits thereof, and the aspects accomplished by the implementation of the disclosure. However, the disclosure is not limited to the embodiments disclosed below, but may be implemented in various different forms.

Hereinafter, embodiments will be described in detail with reference to the attached drawings. The same reference numerals in the drawings denote like elements, and a repeated explanation thereof will not be given.

In this specification, terms such as “first” and “second” are used for the purpose of distinguishing one component from another component without a limiting meaning.

In the following embodiments, the singular expressions in the present specification include the plural expressions unless clearly specified otherwise in context.

In the following embodiments, terms such as include or have represent that the features or elements described in the specification exist, and do not preclude the possibility that one or more other features or elements may be added.

In the following embodiments, when a portion such as a film, a region, and a component is referred to as being above or on other portions, this includes the case in which the portion is directly on other portions as well as the case in which other films, other films, and components are located therebetween.

For convenience of explanation, in the drawings, the size of components may be exaggerated or reduced. Sizes and thicknesses of the elements shown in the drawings are for the purpose of descriptive convenience, and thus the disclosure is not necessarily limited thereto.

When an embodiment is otherwise embodied, a certain process order may be performed differently from the described order. For example, two processes described in succession may be performed substantially simultaneously, or may be performed in an order opposite to the order described.

In this specification, the expression “A and/or B” represents the case of A, B, or A and B. In addition, the expression “at least one of A and B” represents the case of A, B, or A and B.

In this specification, when films, regions, components, and the like are connected, this includes the case in which films, regions, and components are directly connected, or/and the case in which other films, regions, and components are located between the films, regions, and components. For example, when a film, a region, a component, and the like are electrically connected in this specification, this represents the case in which a film, a region, a component, and the like are directly electrically connected, and/or indirect electrical connection in which another film, region, component, and the like are located therebetween.

The x-axis, y-axis, and z-axis are not limited to the three axes of the Cartesian coordinate system, and may be interpreted in a broad sense including them. For example, the x-axis, y-axis, and z-axis may be orthogonal to each other, but may refer to different directions that are not orthogonal to each other.

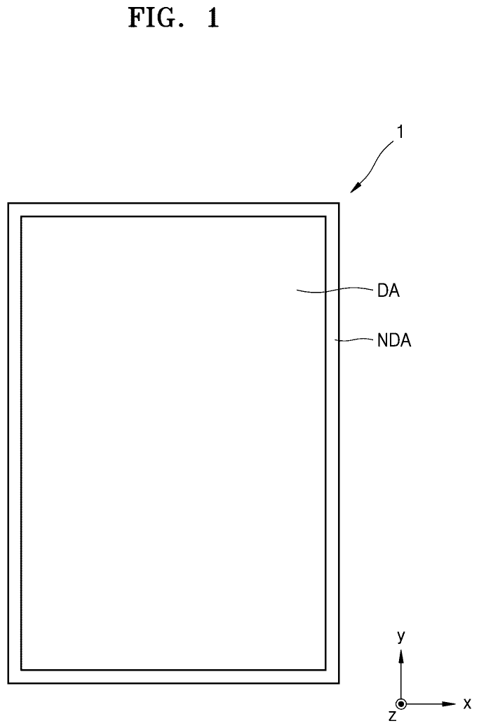

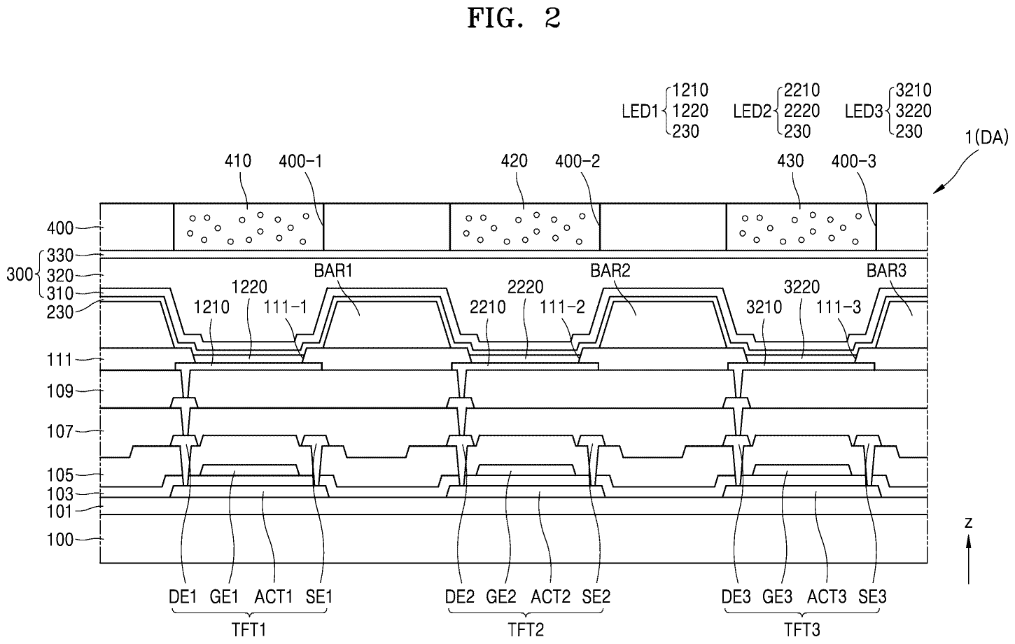

FIG. 1 is a schematic plan view illustrating a display apparatus according to an embodiment. As used herein, the “plan view” is a view in a thickness direction (i.e., z-axis) of the substrate 100 (See FIG. 2).

Referring to FIG. 1, a display apparatus 1 may include a display area DA and a non-display area NDA. In the display area DA, subpixels including a display element such as a light-emitting diode are arranged to provide a certain image. The non-display area NDA may be an area that does not provide an image and may surround the display area DA. In the non-display area NDA, a scan driver and a data driver that provide an electrical signal to be applied to subpixels of the display area DA, and power lines that provide power such as driving voltage and common voltage may be arranged.

Although FIG. 1 illustrates that a length of the display apparatus 1 in an x direction is less than a length in a y direction intersecting with the x direction, the disclosure is not limited thereto. According to another embodiment, a shape of the display apparatus 1 may be changed in various ways, such that the length in the x direction may be greater than the length in the y direction.

FIG. 2 is a cross-sectional view showing a portion of a display apparatus according to an embodiment.

Referring to FIG. 2, light-emitting diodes may be arranged as display elements in the display area DA of the display apparatus 1. For example, a first light-emitting diode LED1, a second light-emitting diode LED2, and a third light-emitting diode LED3 may be arranged in the display area DA of the display apparatus 1. The first light-emitting diode LED1, the second light-emitting diode LED2, and the third light-emitting diode LED3 may emit light of different colors. Each light emitting diode may be connected to a corresponding thin film transistor. For example, the first light-emitting diode LED1 may be connected to a first thin film transistor TFT1, the second light-emitting diode LED2 may be connected to a second thin film transistor TFT2, and the third light-emitting diode LED3 may be connected to a third thin film transistor TFT3. Each thin film transistor may drive a light-emitting diode connected thereto, and the light-emitting diode may emit light of a certain color. According to an embodiment, light beams emitted by respective light-emitting diodes may have different colors. For example, the colors of respective light beams emitted by the first light-emitting diode LED1, the second light-emitting diode LED2, and the third light-emitting diode LED3 may be different from each other.

The first thin film transistor TFT1, the second thin film transistor TFT2, and the third thin film transistor TFT3 may be disposed on a substrate 100. Each thin film transistor may include an active layer, a gate electrode, a source electrode, and a drain electrode.

According to an embodiment, the first thin film transistor TFT1 may include a first active layer ACT1, a first gate electrode GE1, a first source electrode SE1, and a first drain electrode DE1. The first gate electrode GE1 may be disposed on the first active layer ACT1 and may overlap a partial region of the first active layer ACT1 in a plan view, but may be insulated from the first active layer ACT1. The first source electrode SE1 and the first drain electrode DE1 may be disposed on the first active layer ACT1 and overlap a partial region of the first active layer ACT1 in a plan view, but may be connected to the first active layer ACT1.

According to an embodiment, the second thin film transistor TFT2 may include a second active layer ACT2, a second gate electrode GE2, a second source electrode SE2, and a second drain electrode DE2. The second gate electrode GE2 may be disposed on the second active layer ACT2 and may overlap a partial region of the second active layer ACT2 in a plan view, but may be insulated from the second active layer ACT2. The second source electrode SE2 and the second drain electrode DE2 may be disposed on the second active layer ACT2 and overlap a partial region of the second active layer ACT2 in a plan view, but may be connected to the second active layer ACT2.

According to an embodiment, the third thin film transistor TFT3 may include a third active layer ACT3, a third gate electrode GE3, a third source electrode SE3, and a third drain electrode DE3. The third gate electrode GE3 may be disposed on the third active layer ACT3 and may overlap a partial region of the second active layer ACT2 in a plan view, but may be insulated from the third active layer ACT3. The third source electrode SE3 and the third drain electrode DE3 may be disposed on the third active layer ACT3 and overlap a partial region of the third active layer ACT3 in a plan view, but may be connected to the third active layer ACT3.

The first gate electrode GE1, the second gate electrode GE2, the third gate electrode GE3, the first source electrode SE1, the second source electrode SE2, the third source electrode SE3, the first drain electrode DE1, the second drain electrode DE2, and the third drain electrode DE3 may each include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layer or multi-layer structure.

A buffer layer 101 may be located between the substrate 100, and the first active layer ACT1, the second active layer ACT2, and the third active layer ACT3. A gate insulating layer 103 may be located between the first active layer ACT1 and the first gate electrode GE1, between the second active layer ACT2 and the second gate electrode GE2, and between the third active layer ACT3 and the third gate electrode GE3. An interlayer-insulating layer 105 may be located between the first gate electrode GE1, and the first source electrode SE1 and the first drain electrode DE1, between the second gate electrode GE2, and the second source electrode SE2 and the second drain electrode DE2, and between the third gate electrode GE3, and the third source electrode SE3 and the third drain electrode DE3. The buffer layer 101, the gate insulating layer 103, and the interlayer-insulating layer 105 may each include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ), and may have a single-layer or multi-layer structure.

The first source electrode SE1 and the first drain electrode DE1 may be connected to the first active layer ACT1 through contact holes defined in the interlayer-insulating layer 105 and the gate insulating layer 103. The second source electrode SE2 and the second drain electrode DE2 may be connected to the second active layer ACT2 through contact holes defined in the interlayer-insulating layer 105 and the gate insulating layer 103. The third source electrode SE3 and the third drain electrode DE3 may be connected to the third active layer ACT3 through contact holes defined in the interlayer-insulating layer 105 and the gate insulating layer 103.

A first organic insulating layer 107 may be disposed on the first thin film transistor TFT1, the second thin film transistor TFT2, and the third thin film transistor TFT3. According to an embodiment, the first organic insulating layer 107 may cover the first thin film transistor TFT1, the second thin film transistor TFT2, and the third thin film transistor TFT3. The first organic insulating layer 107 may define the contact holes that overlap the first drain electrode DE1, the second drain electrode DE2, and the third drain electrode DE3, respectively, in a plan view. The first organic insulating layer 107 may include an organic insulating material such as acrylic, benzocyclobutene (BCB), polyimide (PI), or hexamethyldisiloxane (HMDSO), but is not necessarily limited thereto.

A contact metal may be disposed on the first organic insulating layer 107. The contact metal may be connected to the first drain electrode DE1, the second drain electrode DE2, and the third drain electrode DE3 through the contact holes of the first organic insulating layer 107, respectively. The contact metal may include aluminum (Al), copper (Cu), and/or titanium (Ti), and may be formed as a single layer or multiple layers including the materials described above.

A second organic insulating layer 109 may be disposed on the contact metal. The second organic insulating layer 109 may define contact holes that overlap the respective contact metals CM in a plan view. The second organic insulating layer 109 may include an organic insulating material such as acrylic, benzocyclobutene (BCB), polyimide (PI), or hexamethyldisiloxane (HMDSO), but is not necessarily limited thereto.

A light-emitting diode may be disposed on the second organic insulating layer 109. For example, the first light-emitting diode LED1, the second light-emitting diode LED2, and the third light-emitting diode LED3 may be disposed on the second organic insulating layer 109. The first light-emitting diode LED1 may include a first subpixel electrode 1210, a first emission layer 1220, and a counter electrode 230. The second light-emitting diode LED2 may include a second subpixel electrode 2210, a second emission layer 2220, and the counter electrode 230. The third light-emitting diode LED3 may include a third subpixel electrode 3210, a third emission layer 3220, and the counter electrode 230. According to an embodiment, the counter electrode 230 may be formed integrally across the first light-emitting diode LED1, the second light-emitting diode LED2, and the third light-emitting diode LED3.

The first subpixel electrode 1210, the second subpixel electrode 2210, and the third subpixel electrode 3210 may be spaced apart from each other on a top surface of the second organic insulating layer 109. The first subpixel electrode 1210, the second subpixel electrode 2210, and the third subpixel electrode 3210 may be connected to a corresponding contact metal through the contact holes defined in the second organic insulating layer 109. The first subpixel electrode 1210, the second subpixel electrode 2210, and the third subpixel electrode 3210 may be connected to a corresponding thin film transistor through a corresponding contact metal. According to an embodiment, the first subpixel electrode 1210 may be connected to the first drain electrode DE1 of the first thin film transistor TFT1 through a corresponding contact metal. According to an embodiment, the second subpixel electrode 2210 may be connected to the second drain electrode DE2 of the second thin film transistor TFT2 through a corresponding contact metal. According to an embodiment, the third subpixel electrode 3210 may be connected to the third drain electrode DE3 of the third thin film transistor TFT3 through a corresponding contact metal.

According to the embodiment illustrated in FIG. 2, the first thin film transistor TFT1, the second thin film transistor TFT2, and the third thin film transistor TFT3 may be electrically connected to the first subpixel electrode 1210, the second subpixel electrode 2210, and the third subpixel electrode 3210, respectively, through the contact metals CM. However, the disclosure is not necessarily limited thereto. According to another embodiment, the display apparatus 1 may have only one organic insulating layer, the contact metal may be omitted, and each subpixel electrode may be directly connected to a corresponding thin film transistor. According to another embodiment, the display apparatus 1 may have three or more organic insulating layers and may include a plurality of contact metals arranged between the organic insulating layers.

According to an embodiment, the first subpixel electrode 1210, the second subpixel electrode 2210, and the third subpixel electrode 3210 may be formed to be reflective electrodes. For example, the first subpixel electrode 1210, the second subpixel electrode 2210, and the third subpixel electrode 3210 may be formed by forming a reflective film by using silver (Ag), magnesium (Mg), aluminum (Al), platinum (Pt), palladium (Pd), gold (Au), nickel (Ni), neodymium (Nd), iridium (Ir), chromium (Cr), or a compound thereof, and disposing a film including ITO, IZO, ZnO, or In₂O₃ on the reflective film. According to an embodiment, the first subpixel electrode 1210, the second subpixel electrode 2210, and the third subpixel electrode 3210 may each have a structure in which an ITO layer, an Ag layer, and an ITO layer are sequentially stacked. The disclosure is not limited thereto, and the first subpixel electrode 1210, the second subpixel electrode 2210, and the third subpixel electrode 3210 may include various materials and may be modified in various ways, such as being single-layered or multi-layered. The first subpixel electrode 1210, the second subpixel electrode 2210, and the third subpixel electrode 3210 may include different materials and may also have different structures.

A pixel definition layer 111 may be disposed on the second organic insulating layer 109. According to an embodiment, the pixel definition layer 111 may cover an edge area (or edge) of each of the first subpixel electrode 1210, the second subpixel electrode 2210, and the third subpixel electrode 3210. In other words, the pixel definition layer 111 may be opened to expose a central portion of each of the first subpixel electrode 1210, the second subpixel electrode 2210, and the third subpixel electrode 3210. According to an embodiment, the pixel definition layer 111 may define a first opening 111-1 that overlaps the first subpixel electrode 1210 in a plan view. According to an embodiment, the pixel definition layer 111 may define a second opening 111-2 that overlaps the second subpixel electrode 2210 in a plan view. According to an embodiment, the pixel definition layer 111 may define a third opening 111-3 that overlaps the third subpixel electrode 3210 in a plan view.

A corresponding emission layer may be disposed on each subpixel electrode. According to an embodiment, the first emission layer 1220 may be disposed on the first subpixel electrode 1210. According to an embodiment, the first emission layer 1220 may be located in the first opening 111-1 of the pixel definition layer 111. According to an embodiment, the second emission layer 2220 may be disposed on the second subpixel electrode 2210. According to an embodiment, the second emission layer 2220 may be located in the second opening 111-2 of the pixel definition layer 111. According to an embodiment, the third emission layer 3220 may be disposed on the third subpixel electrode 3210. According to an embodiment, the third emission layer 3220 may be located in the third opening 111-3 of the pixel definition layer 111.

Each emission layer, for example, the first emission layer 1220, the second emission layer 2220, and the third emission layer 3220, may include a material that emits light of a certain color when voltage is applied to each emission layer. According to an embodiment, the first emission layer 1220, the second emission layer 2220, and the third emission layer 3220 may include organic materials. According to an embodiment, the first emission layer 1220, the second emission layer 2220, and the third emission layer 3220 may include inorganic materials. According to an embodiment, the first emission layer 1220, the second emission layer 2220, and the third emission layer 3220 may include quantum dots. Although not shown in FIG. 2, a functional layer including at least one of a hole injection layer, a hole transportation layer, an electron injection layer, and an electron transportation layer may be disposed above and/or below each of the first emission layer 1220, the second emission layer 2220, and the third emission layer 3220.

A barrier layer may be located on the pixel definition layer 111. According to an embodiment, a first barrier BAR1 may be disposed on the pixel definition layer 111 between the first subpixel electrode 1210 and the second subpixel electrode 2210. According to an embodiment, a second barrier BAR2 may be disposed on the pixel definition layer 111 between the second subpixel electrode 2210 and the third subpixel electrode 3210. According to an embodiment, a third barrier BAR3 may be located at an opposite side to the second barrier BAR2 based on the third subpixel electrode 3210. The first barrier BAR1, the second barrier BAR2, and the third barrier BAR3 may include tapered lateral surfaces with respect to a top surface of the pixel definition layer 111. Detailed shapes and sizes of the first barrier BAR1, the second barrier BAR2, and the third barrier BAR3 will be described below. According to an embodiment, the first barrier BAR1, the second barrier BAR2, and the third barrier BAR3 may include a light-shielding material.

The counter electrode 230 may be disposed on the first barrier BAR1, the second barrier BAR2, and the third barrier BAR3. According to an embodiment, the counter electrode 230 may cover the first barrier BAR1, the second barrier BAR2, and the third barrier BAR3. According to an embodiment, the counter electrode 230 may be in direct contact with the first emission layer 1220, the second emission layer 2220, and the third emission layer 3220. According to an embodiment, the counter electrode 230 may be formed integrally over the entire display area DA.

The counter electrode 230 may include a conductive material. For example, the counter electrode 230 may include silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof.

An encapsulation layer 300 may be disposed on the counter electrode 230. The encapsulation layer 300 may include one or more inorganic encapsulation layers and one or more organic encapsulation layers. For example, the encapsulation layer 300 may include a first inorganic encapsulation layer 310, an organic encapsulation layer 320, and a second inorganic encapsulation layer 330. According to an embodiment, the first inorganic encapsulation layer 310 may be disposed on the counter electrode 230 and may cover the entirety of the counter electrode 230. According to an embodiment, the second inorganic encapsulation layer 330 may be disposed on the first inorganic encapsulation layer 310. According to an embodiment, the organic encapsulation layer 320 may be located between the first inorganic encapsulation layer 310 and the second inorganic encapsulation layer 330. According to an embodiment, the second inorganic encapsulation layer 330 may cover the entirety of the organic encapsulation layer 320. According to an embodiment, the organic encapsulation layer 320 may be a planarization layer that planarizes a curve of a top surface of the first inorganic encapsulation layer 310.

The first inorganic encapsulation layer 310 and/or the second inorganic encapsulation layer 330 may include an inorganic insulating material such as aluminum oxide (AlOₓ), titanium oxide (TiOₓ), tantalum oxide (TaOₓ), hafnium oxide (HfOₓ), zinc oxide (ZnOₓ), silicon oxide (SiOₓ), silicon nitride (SiNₓ), and silicon oxynitride (SiON), and may have a single-layer or multi-layer structure.

The organic encapsulation layer 320 may include an organic insulating material such as polyethylene terephthalate (“PET”), polyethylene naphthalate (“PEN”), polycarbonate (“PC”), polyimide (“PI”), polyethylene sulfonate (“PES”), polyoxymethylene (“POM”), polyarylate (“PAR”), and hexamethyldisiloxane (“HMDSO”), and may have a single-layer or multi-layer structure.

A color element layer may be located on the encapsulation layer 300. The color element layer may include a bank layer 400, a first color element 410, a second color element 420, and a third color element 430. According to an embodiment, the bank layer 400 may be disposed on the second inorganic encapsulation layer 330. According to an embodiment, the bank layer 400 may include a first hole 400-1 that overlaps the first subpixel electrode 1210 in a plan view. According to an embodiment, the bank layer 400 may include a second hole 400-2 that overlaps the second subpixel electrode 2210 in a plan view. According to an embodiment, the bank layer 400 may include a third hole 400-3 that overlaps the third subpixel electrode 3210 in a plan view.

Each color element may be located within a corresponding hole of the bank layer 400. According to an embodiment, the first color element 410 may be located within the first hole 400-1 of the bank layer 400. According to an embodiment, the second color element 420 may be located within the second color element 420 of the bank layer 400. According to an embodiment, the third color element 430 may be located within the third color element 430 of the bank layer 400.

Each color element may include quantum dots. For example, the first color element 410 may include a first quantum dot, the second color element 420 may include a second quantum dot, and the third color element 430 may include a third quantum dot. Quantum dots may be excited by incident light and emit light of a certain wavelength. According to an embodiment, a first quantum dot of the first color element 410 may be excited by incident light emitted from the first light-emitting diode LED1 to emit light (e.g., red light) having a certain wavelength, i.e., a certain color. According to an embodiment, a second quantum dot of the second color element 420 may be excited by incident light emitted from the second light-emitting diode LED2 to emit light (e.g., green light) having a certain wavelength, i.e., a certain color. According to an embodiment, a third quantum dot of the third color element 430 may be excited by incident light emitted from the third light-emitting diode LED3 to emit light (e.g., blue light) having a certain wavelength, i.e., a certain color.

For example, according to an embodiment, the first light-emitting diode LED1, the second light-emitting diode LED2, and the third light-emitting diode LED3 may emit white light, the first quantum dot of the first color element 410 may be excited by the white light to emit red light, the second quantum dot of the second color element 420 may be excited by the white light to emit green light, and the third quantum dot of the third color element 430 may be excited by the white light to emit blue light.

A core of the quantum dot described above may be selected from a group II-VI compound, a group III-V compound, a group IV-VI compound, a group IV element, a group IV compound, and a combination thereof.

The group II-VI compound may selected from the group including a binary compound selected from the group consisting of CdSe, CdTe, ZnS, ZnSe, ZnTe, ZnO, HgS, HgSe, HgTe, MgSe, MgS, and mixtures thereof, a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of a binary compound selected from the group consisting of GaN, GaP, GaAs, GaSb, AlN, AIP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAINP, and mixtures thereof, and a quaternary compound selected from the group consisting of GaAINAs, GaAINSb, GaAlPAs, GaAlPSb, GaInNP, GaInNAs, GaInNSb, GalnPAs, GaInPSb, InAINP, InAINAs, InAINSb, InAlPAs, InAlPSb, and mixtures thereof.

The group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may include a binary compound selected from the group consisting of SiC, SiGe, and mixtures thereof.

In this case, the binary compound, the ternary compound, and the quaternary compound may be present within a particle at a uniform concentration or may be present in the same particle while being divided into states with partially different concentration distributions. One quantum dot may have a core/shell structure surrounding another quantum dot. An interface between the core and the shell may have a concentration gradient in which a concentration of elements present in the shell decreases toward the center.

In some embodiments, a quantum dot may have a core-shell structure including a core including the nanocrystal described above and a shell surrounding the core. The shell of the quantum dot may function as a protective layer to maintain semiconductor properties by preventing chemical modification of the core and/or as a charging layer to impart electrophoretic properties to the quantum dot. The shell may be single-layered or multi-layered. An interface between the core and the shell may have a concentration gradient in which a concentration of elements present in the shell decreases toward the center. Examples of the shell of the quantum dot may include a metal or non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO or a ternary compound such as MgAl₂O₄, CoFe₂O₄, NiFe₂O₄, and CoMn₂O₄, but the disclosure is not limited thereto.

For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, and AlSb, but the disclosure is not limited thereto.

According to an embodiment, one of the first color element 410, the second color element 420, and the third color element 430 may not include a quantum dot and may include a light-transmitting material. For example, according to an embodiment, the first light-emitting diode LED1, the second light-emitting diode LED2, and the third light-emitting diode LED3 may emit blue light, the first quantum dot of the first color element 410 may be excited by the blue light to emit red light, the second quantum dot of the second color element 420 may be excited by the blue light to emit green light, and the third color element 430 may include a light-transmitting material to transmit blue light therethrough.

A certain component of the light emitted from each of the first light-emitting diode LED1, the second light-emitting diode LED2, and the third light-emitting diode LED3 may be directed toward an adjacent color element rather than toward a corresponding color element. For example, some of the light emitted from the first light-emitting diode LED1 (hereinafter, first planar light) may not be directed toward the first color element 410, but may be directed toward the second color element 420 and/or the third color element 430. When the first planar light reaches the second color element 420 and/or the third color element 430, this may affect the color of light emitted from the second color element 420 and/or the third color element 430 and further reduce a color reproduction rate of the display apparatus 1. According to an embodiment, the first barrier BAR1 and/or the second barrier BAR2 may prevent the first planar light from reaching the second color element 420 and/or the third color element 430. As used herein, the “planar light” is a light emitted from a plane surface.

Similarly, some of the light emitted from the second light-emitting diode LED2 (hereinafter, second planar light) may not be directed toward the second color element 420, but may be directed toward the first color element 410 and/or the third color element 430. When the second planar light reaches the first color element 410 and/or the third color element 430, this may affect the color of light emitted from the first color element 410 and/or the third color element 430 and further reduce a color reproduction rate of the display apparatus 1. The first barrier BAR1 and/or the third barrier BAR3 may prevent the second planar light from reaching the first color element 410 and/or the third color element 430.

Similarly, some of the light emitted from the third light-emitting diode LED3 (hereinafter, third planar light) may not be directed toward the third color element 430, but may be directed toward the first color element 410 and/or the second color element 420. When the third planar light reaches the first color element 410 and/or the second color element 420, this may affect the color of light emitted from the first color element 410 and/or the second color element 420 and further reduce a color reproduction rate of the display apparatus 1. The first barrier BAR1 and/or the second barrier BAR2 may prevent the third planar light from reaching the first color element 410 and/or the second color element 420.

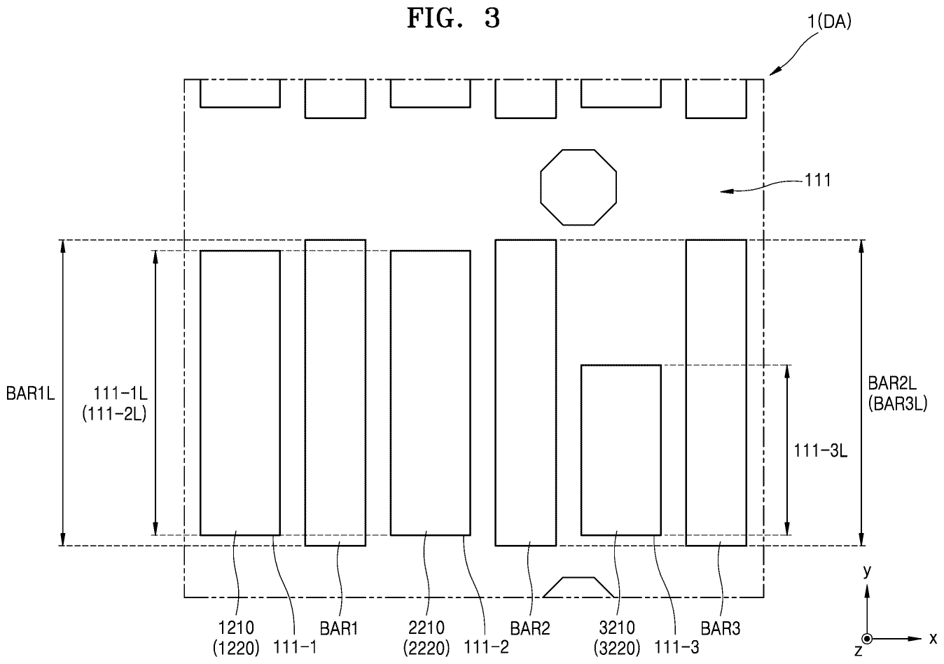

FIG. 3 is an enlarged plan view of a portion of a display apparatus according to an embodiment.

Referring to FIG. 3, in the display area DA, each subpixel electrode and a corresponding emission layer may be spaced apart from each other. The first subpixel electrode 1210, the second subpixel electrode 2210, and the third subpixel electrode 3210 may be spaced apart from each other in the display area DA. The first emission layer 1220 may be disposed on the first subpixel electrode 1210. The second emission layer 2220 may be disposed on the second subpixel electrode 2210. The third emission layer may be disposed on the third subpixel electrode 3210.

The pixel definition layer 111 may include an opening that overlaps each subpixel electrode in a plan view. For example, the pixel definition layer 111 may include the first opening 111-1 overlapping the first subpixel electrode 1210, the second opening 111-2 overlapping the second subpixel electrode 2210, and the third opening 111-3 overlapping the third subpixel electrode 3210 in a plan view. The pixel definition layer 111 may cover an edge area (or edge) of each subpixel electrode. FIG. 3 illustrates the case in which a portion (e.g., a central portion) of a subpixel electrode corresponding to each opening is exposed.

According to an embodiment, the first barrier BAR1 may be located between the first opening 111-1 and the second opening 111-2 or between the first subpixel electrode 1210 and the second subpixel electrode 2210. According to an embodiment, the first barrier BAR1 may be located in a +x direction based on the first opening 111-1 (or the first subpixel electrode 1210). According to an embodiment, the first barrier BAR1 may be located in a −x direction based on the second opening (or the second subpixel electrode 2210).

According to an embodiment, the second barrier BAR2 may be located between the second opening 111-2 and the third opening 111-3 or between the second subpixel electrode 2210 and the third subpixel electrode 3210. According to an embodiment, the second barrier BAR2 may be located in a +x direction based on the second opening 111-2 (or the second subpixel electrode 2210). According to an embodiment, the second barrier BAR2 may be located in a −x direction based on the third opening (or the third subpixel electrode 3210).

According to an embodiment, the third barrier BAR3 may be located in a +x direction based on the third opening (or the third subpixel electrode 3210).

Each opening and each barrier of the pixel definition layer 111 may have a shape extending in one axis (e.g., the y-axis). According to an embodiment, the first opening 111-1, the second opening 111-2, and the third opening 111-3 may have an approximately rectangular shape having a short side extending along the x-axis and a long side extending along the y-axis. In other words, the first opening 111-1, the second opening 111-2, and the third opening 111-3 may have an approximately rectangular shape extending in the y-axis. According to an embodiment, the first barrier BAR1, the second barrier BAR2, and the third barrier BAR3 may have an approximately rectangular shape having a short side extending along the x-axis and a long side extending along the y-axis. In other words, the first barrier BAR1, the second barrier BAR2, and the third barrier BAR3 may have an approximately rectangular shape extending in the y-axis.

A length of the long side (e.g., a side extending along the y-axis) of the first opening 111-1 is defined as a first length 111-1L. A length of the long side (e.g., a side extending along the y-axis) of the second opening 111-2 is defined as a second length 111-2L. A length of the long side (e.g., a side extending along the y-axis) of the third opening 111-3 is defined as a third length 111-3L. A length of the long side (e.g., a side extending along the y-axis) of the first barrier BAR1 is defined as a fourth length BAR1L. A length of the long side (e.g., a side extending along the y-axis) of the second barrier BAR2 is defined as a fifth length BAR2L. A length of the long side (e.g., a side extending along the y-axis) of the third barrier BAR3 is defined as a sixth length BAR3L.

According to an embodiment, the first length 111-1L and the second length 111-2L in the y direction may be equal. According to an embodiment, the first length 111-1L and the second length 111-2L may each be greater than the third length 111-3L in the y direction. According to an embodiment, the fourth length BAR1L and the fifth length BAR2L may be equal to each other. According to an embodiment, the fifth length BAR2L and the sixth length BAR3L may be equal to each other. According to an embodiment, the fourth length BAR1L and the sixth length BAR3L may be equal to each other. According to an embodiment, the fourth length BAR1L, the fifth length BAR2L, and the sixth length BAR3L may be equal to one another.

A length of each barrier may be greater than a length of a light-emitting area of a light-emitting diode, i.e., an opening of the pixel definition layer 111. Accordingly, each barrier may effectively block the planar light described above (e.g., the first to third planar light). According to an embodiment, the fourth length BAR1L may be greater than each of the first length 111-1L and the second length 111-2L in the y direction. According to an embodiment, the fourth length BAR1L in the y direction may be greater than each of the first length 111-1L and the second length 111-2L by about 6 micrometers (μm) or more. According to an embodiment, the fifth length BAR2L may be greater than each of the second length 111-2L and the third length 111-3L. According to an embodiment, the fifth length BAR2L may be greater than the second length 111-2L by about 6 micrometers (μm) or more. According to an embodiment, the sixth length BAR3L may be greater than the third length 111-3L in the y direction.

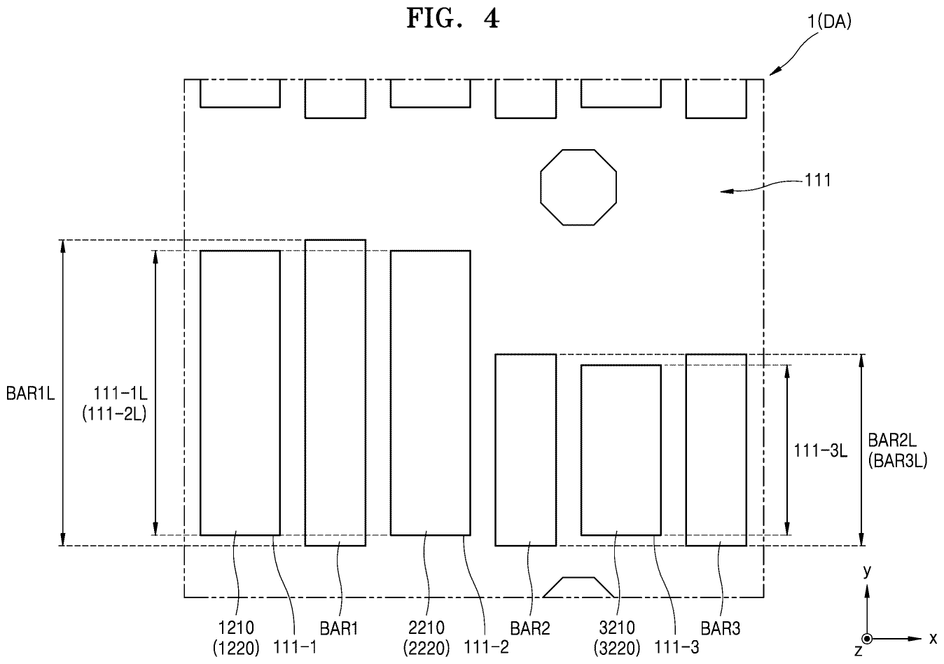

FIG. 4 is an enlarged plan view of a portion of a display apparatus according to an embodiment.

Referring to FIG. 4, compared to the embodiment illustrated in FIG. 3, the length of the second barrier BAR2 may be different from the length of the third barrier BAR3.

According to an embodiment, the fifth length BAR2L and the sixth length BAR3L may be equal to each other. According to an embodiment, the fifth length BAR2L and the sixth length BAR3L may each be less than the fourth length BAR1L in the y direction. According to an embodiment, the fifth length BAR2L and the sixth length BAR3L may each be less than the first length 111-1L. According to an embodiment, the fifth length BAR2L and the sixth length BAR3L may each be less than the second length 111-2L. According to an embodiment, the fifth length BAR2L and the sixth length BAR3L may each be greater than the third length 111-3L in the y direction. According to an embodiment, the fifth length BAR2L and the sixth length BAR3L may each be greater than the third length 111-3L by about 6 micrometers (μm) or more.

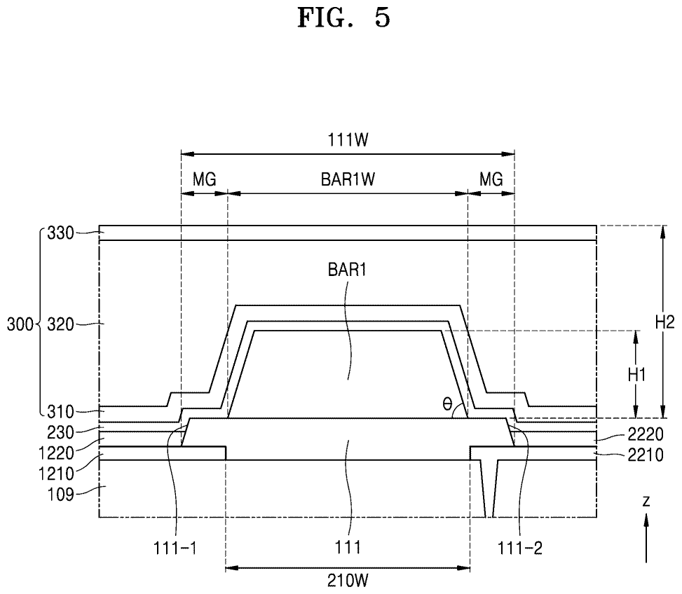

FIG. 5 is an enlarged cross-sectional view of a portion of a display apparatus according to an embodiment.

The aspects described below based on the first barrier BAR1 are not limited to the first barrier BAR1 and may also be applied to the second barrier BAR2 and the third barrier BAR3.

Referring to FIG. 5, the first subpixel electrode 1210, the second subpixel electrode 2210, and the pixel definition layer 111 may be disposed on the second organic insulating layer 109. The pixel definition layer 111 may include the first opening 111-1 exposing a central portion of the first subpixel electrode 1210, and the second opening 111-2 exposing a central portion of the second subpixel electrode 2210. The first emission layer 1220 may be disposed on the first subpixel electrode 1210. The second emission layer 2220 may be disposed on the second subpixel electrode 2210.

The first barrier BAR1 may be disposed on the pixel definition layer 111. According to an embodiment, the first barrier BAR1 may be located between the first opening 111-1 and the second opening 111-2. According to an embodiment, the first barrier BAR1 may be located between the first subpixel electrode 1210 and the second subpixel electrode 2210.

According to an embodiment, a width BAR1W of the first barrier BAR1, for example, a width BAR1W of a bottom surface of the first barrier BAR1 in the x direction, may be less than a distance between an edge of the pixel definition layer 111, which defines the first opening 111-1, and an edge of the pixel definition layer 111, which defines the second opening 111-2. For example, the width BAR1W of the bottom surface of the first barrier BAR1 may be less than a width of a top surface of the pixel definition layer 111 in the x direction. Accordingly, the edge of the bottom surface of the first barrier BAR1 may be spaced apart from the edge of the top surface of the pixel definition layer 111. According to an embodiment, the width BAR1W of the first barrier BAR1 may be less than a width 111W of the pixel definition layer 111 in the x direction.

According to an embodiment, a process margin MG may be present between an edge of the pixel definition layer 111, which is in contact with the first subpixel electrode 1210, and an edge of the first barrier BAR1, which is in contact with the pixel definition layer 111, (e.g., the edge of the bottom surface of the first barrier BAR1). According to an embodiment, the process margin MG may be present between an edge of the pixel definition layer 111, which is in contact with the second subpixel electrode 2210, and an edge of the first barrier BAR1, which is in contact with the pixel definition layer 111, (e.g., the edge of the bottom surface of the first barrier BAR1). According to an embodiment, the process margin MG may be about 3 micrometers (μm). According to an embodiment, the width BAR1W of the first barrier BAR1 may be less than the width 111W of the pixel definition layer 111 by twice the process margin MG. According to an embodiment, the width BAR1W of the first barrier BAR1 may be less than the width 111W of the pixel definition layer 111 by about 6 micrometers (μm). According to an embodiment, the width BAR1W of the first barrier BAR1 may be equal to a distance 210W between the first subpixel electrode 1210 and the second subpixel electrode 2210 in the x direction.

According to an embodiment, in the first barrier BAR1, a width of a top surface may be less than a width of a bottom surface. In other words, the first barrier BAR1 may include a tapered lateral surface with respect to the top surface of the pixel definition layer 111. For example, the lateral surface of the first barrier BAR1 may define a certain angle θ with respect to the top surface of the pixel definition layer 111. According to an embodiment, the angle θ may be equal to or less than 90 degrees. According to an embodiment, the angle θ may be equal to or more than 90 degrees. According to an embodiment, the angle θ may be from about 30 degrees to 90 degrees.

The counter electrode 230, the first inorganic encapsulation layer 310, the organic encapsulation layer 320, and the second inorganic encapsulation layer 330 may be sequentially arranged on the first barrier BAR1. According to an embodiment, the organic encapsulation layer 320 may be a planarization layer and may planarize a protrusion caused by the first barrier BAR1. According to an embodiment, a thickness H1 of the first barrier BAR1 may be less than a thickness H2 of the encapsulation layer 300 in the z-axis direction. In other words, a distance H1 from a top surface of the pixel definition layer 111 to a top surface of the first barrier BAR1 may be less than a distance H2 to a top surface of the encapsulation layer 300 (e.g., to a top surface of the second inorganic encapsulation layer 330) from the top surface of the pixel definition layer 111. Accordingly, the first barrier BAR1 may be planarized by the encapsulation layer 300 (e.g., the organic encapsulation layer 320) and a top surface of the encapsulation layer 300 (e.g., a top surface of the second inorganic encapsulation layer 330) may not protrude. According to an embodiment, the distance H1 from the top surface of the pixel definition layer 111 to the top surface of the first barrier BAR1 may be about 2 micrometers (μm). According to an embodiment, the distance H2 from the top surface of the pixel definition layer 111 to the top surface of the encapsulation layer 300 may be about 3 micrometers (μm).

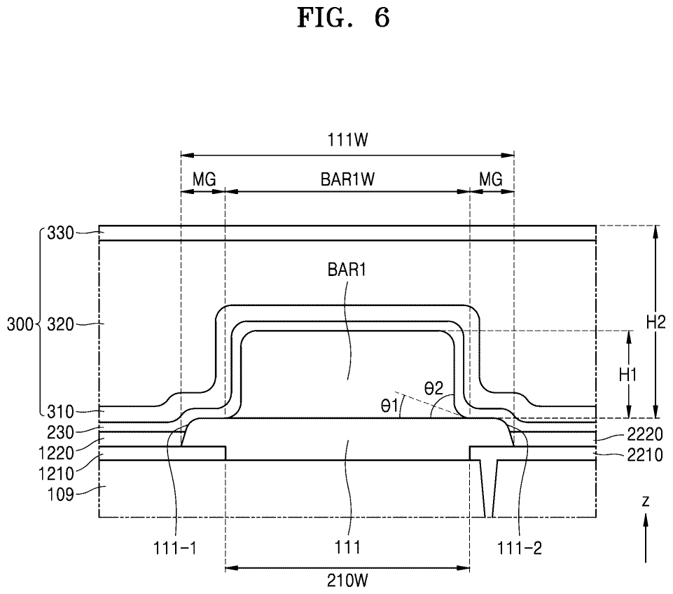

FIG. 6 is an enlarged cross-sectional view of a portion of a display apparatus according to an embodiment.

Referring to FIG. 6, a lateral surface of the first barrier BAR1 may include a rounded portion, i.e., a curved surface. Therefore, an angle formed by the lateral surface of the first barrier BAR1 and the top surface of the pixel definition layer 111 may not be constant.

According to an embodiment, the minimum angle formed by a tangent line in contact with the lateral surface of the first barrier BAR1 and the top surface of the pixel definition layer 111 may be a first angle θ1. According to an embodiment, the first angle θ1 may be about 90 degrees. According to an embodiment, the maximum angle formed by a tangent line in contact with the lateral surface of the first barrier BAR1 and the top surface of the pixel definition layer 111 may be a second angle θ2. According to an embodiment, the second angle θ2 may be about 90 degrees. Therefore, an angle formed by the lateral surface of the first barrier BAR1 and the top surface of the pixel definition layer 111 may be from about 30 degrees to 90 degrees.

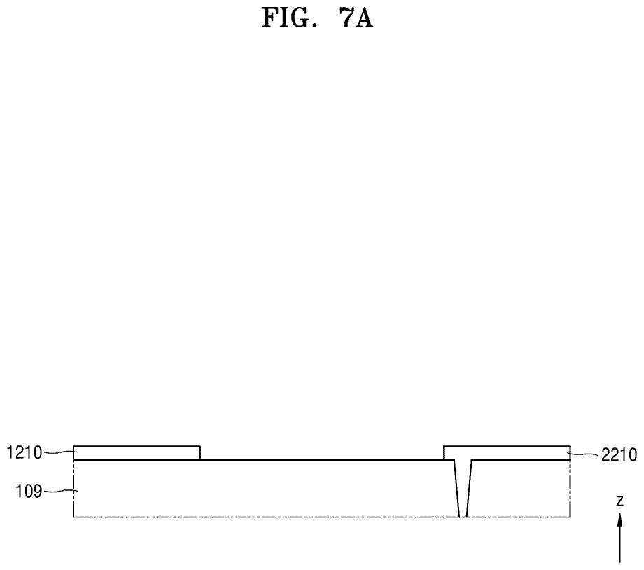

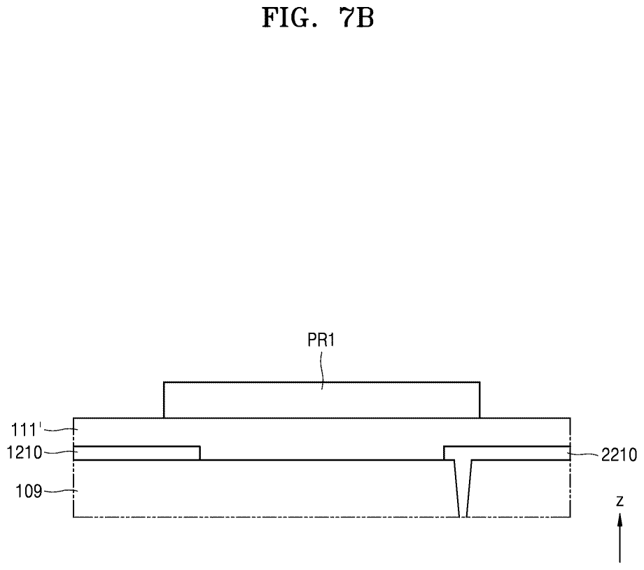

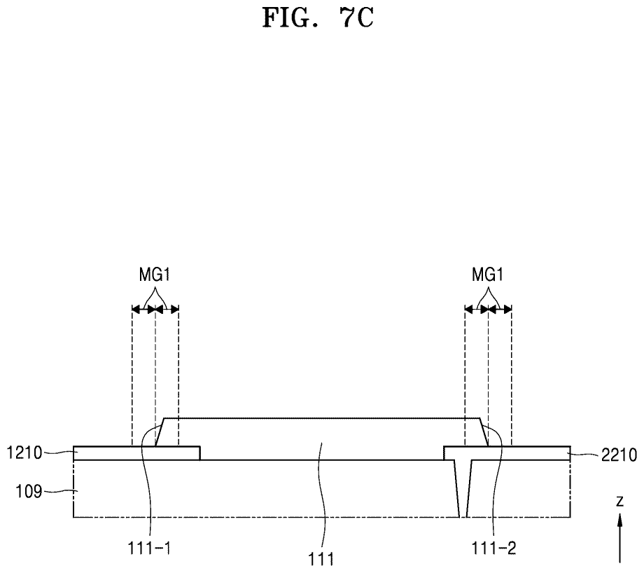

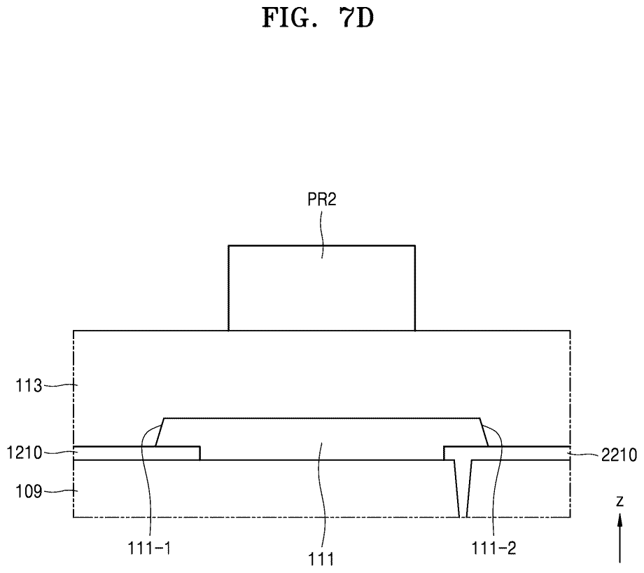

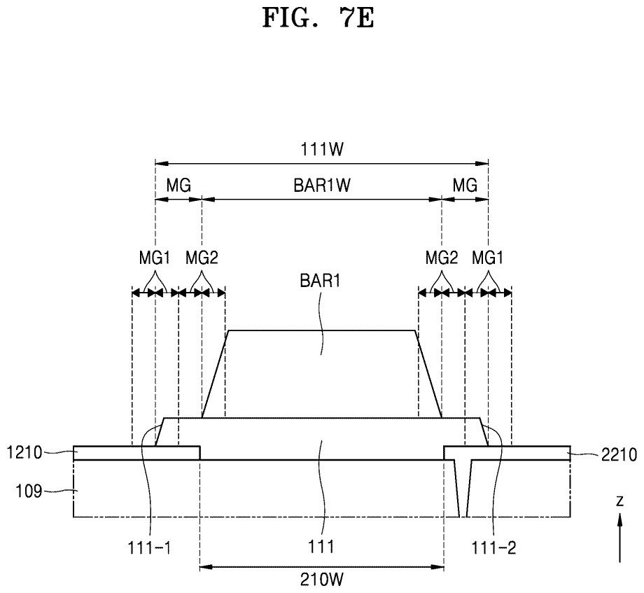

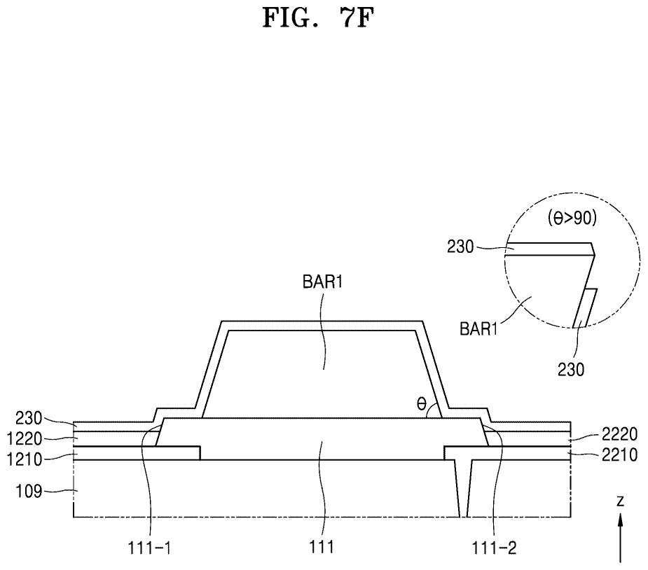

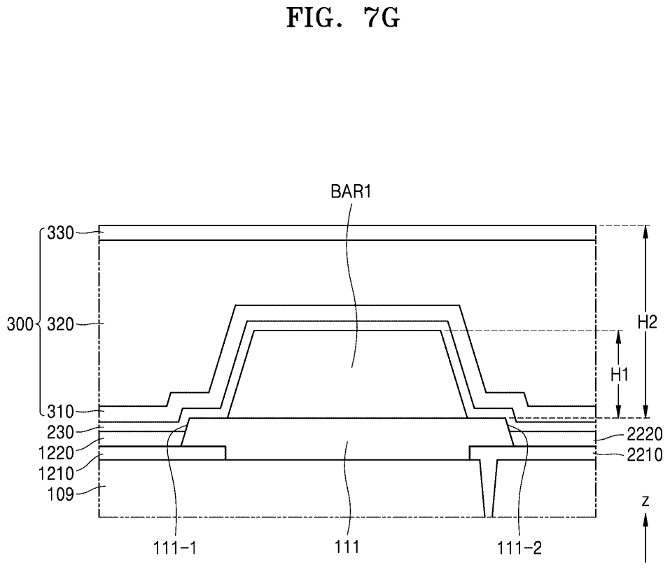

FIGS. 7A, 7B, 7C, 7D, 7E, 7F, and 7G are cross-sectional views showing operations in a manufacturing process of a display apparatus according to an embodiment.

Referring to FIG. 7A, the first subpixel electrode 1210 and the second subpixel electrode 2210 may be spaced apart from each other on the second organic insulating layer 109.

Referring to FIG. 7b, a first material layer 111′ may be located to cover the first subpixel electrode 1210 and the second subpixel electrode 2210. The first material layer 111′ may include the same material as the pixel definition layer 111 (refer to FIG. 2) described above. A first photoresist PR1 may be disposed on the first material layer 111′. The first photoresist PR1 may partially overlap the first subpixel electrode 1210 and partially overlap the second subpixel electrode 2210 in a plan view.

Referring to FIGS. 7B and 7C together, the first material layer 111′ may be etched to form the pixel definition layer 111. In this case, the first material layer 111′ may be etched using the first photoresist PR1 as a mask. According to an embodiment, the first material layer 111′ may be etched to form the first opening 111-1 and the second opening 111-2. For example, the first opening 111-1 may be formed by etching the first material layer 111′ in an area that overlaps the first subpixel electrode 1210 in a plan view, and the second opening 111-2 may be formed by etching the first material layer 111′ in an area that overlaps the second subpixel electrode 2210 in a plan view. A portion of the first material layer 111′ remaining after etching may be understood as the pixel definition layer 111.

During etching, a margin may be generated at the edge position of the pixel definition layer 111 defining the first opening 111-1. For example, a first process margin MG1 may be present at a location of an edge of the pixel definition layer 111 defining the first opening 111-1. In other words, the edge of the pixel definition layer 111 defining the first opening 111-1 may be located within a range of twice the first process margin MG1. Similarly, a margin may be generated at the edge position of the pixel definition layer 111 defining the second opening 111-2. For example, the first process margin MG1 may be generated at the edge position of the pixel definition layer 111 defining the second opening 111-2. In other words, the edge of the pixel definition layer 111 defining the second opening 111-2 may be located within a range of twice the first process margin MG1. According to an embodiment, the first process margin MG1 may be about 1.5 micrometers (μm).

Referring to FIG. 7D, a second material layer 113 may be located to cover the first subpixel electrode 1210, the second subpixel electrode 2210, and the pixel definition layer 111. The second material layer 113 may include the same material as the first barrier BAR1 (refer to FIG. 5) described above. A second photoresist PR2 may be disposed on the second material layer 113. The second photoresist PR2 may overlap the pixel definition layer 111 in a plan view.

Referring to FIGS. 7D and 7E together, the second material layer 113 may be etched to form the first barrier BAR1. In this case, the second material layer 113 may be etched using the second photoresist PR2 as a mask. According to an embodiment, the second material layer 113 may be etched in an area overlapping the first subpixel electrode 1210 in a plan view, and the second material layer 113 may be etched in an area overlapping the second subpixel electrode 2210 in a plan view. A portion of the second material layer 113 remaining after etching may be understood as the first barrier BAR1.

During etching, a margin may be generated at the position of each edge of the first barrier BAR1. For example, a second process margin MG2 may be present at each edge of the first barrier BAR1. In other words, each edge of the first barrier BAR1 may be located within a range of twice the second process margin MG2. According to an embodiment, the second process margin MG2 may be about 1.5 micrometers (μm).

According to an embodiment, the process margin MG described above may be the sum of the first process margin MG1 and the second process margin MG2. According to an embodiment, the process margin MG may be about 3 micrometers (μm), the first process margin MG1 may be about 1.5 micrometers (μm), and the second process margin MG2 may be about 1.5 micrometers (μm). According to an embodiment, the width 111W of the pixel definition layer 111 and the width BAR1W of the first barrier BAR1 may be designed according to a relationship between the process margin MG, the first process margin MG1, and the second process margin MG2. For example, the first process margin MG1 and the second process margin MG2 may each be about 1.5 micrometers (μm), and thus the process margin MG may be about 3 micrometers (μm), and the width BAR1W of the first barrier BAR1 may be designed to be less than the width 111W of the pixel definition layer 111 by twice the process margin MG), that is, by about 6 micrometers (μm). To this end, the sizes of the first photoresist PR1 (refer to FIG. 7b) and the second photoresist PR2 (refer to FIG. 7D) described above may be appropriately adjusted. Accordingly, the edge of the first barrier BAR1 may be prevented from protruding beyond the edge of the pixel definition layer 111. This is an example, and the disclosure is not limited to these figures.

Referring to FIG. 7F, the first emission layer 1220, the second emission layer 2220, and the counter electrode 230 may be arranged. The first emission layer 1220 may be located in the first opening 111-1 and may be in contact with the first subpixel electrode 1210. The second emission layer 2220 may be located in the second opening 111-2 and may be in contact with the second subpixel electrode 2210. The counter electrode 230 may be disposed on the first emission layer 1220, the first barrier BAR1, and the second emission layer 2220.

In this case, the first barrier BAR1 may include a tapered lateral surface with respect to the top surface of the pixel definition layer 111. Therefore, an angle θ formed by the lateral surface of the first barrier BAR1 and the top surface of the pixel definition layer 111 may be from about 30 degrees to 90 degrees, as described above. Accordingly, when the counter electrode 230 is located on the first barrier BAR1, the counter electrode 230 may be formed integrally without being disconnected from the edge of the top surface of the first barrier BAR1.

For comparison, a case in which the angle θ is greater than 90 degrees is shown within a circle at an upper-right side of FIG. 7F. When the angle θ is greater than 90 degrees, a portion of the lateral surface of the first barrier BAR1 may have a portion in which the counter electrode 230 is not located, i.e., a portion that is not covered by the counter electrode 230. Accordingly, the counter electrode 230 may be disconnected at an edge of the top surface of the first barrier BAR1. According to an embodiment, the angle θ is equal to or less than 90 degrees to prevent such a phenomenon from occurring.

Referring to FIG. 7G, the encapsulation layer 300 may be disposed on the counter electrode 230. The encapsulation layer 300 may include the first inorganic encapsulation layer 310, the organic encapsulation layer 320, and the second inorganic encapsulation layer 330. As described above, the distance H1 from the top surface of the pixel definition layer 111 to the top surface of the first barrier BAR1 may be less than the distance H2 to the top surface of the encapsulation layer 300 (e.g., to the top surface of the second inorganic encapsulation layer 330) from the top surface of the pixel definition layer 111. According to an embodiment, H1 may be about 2 micrometers (μm) and H2 may be about 3 micrometers (μm).

The display apparatus according to the above-mentioned embodiments may be applied to various electronic devices. An electronic device according to an embodiment may include the above-mentioned display apparatus, along with other modules or apparatuses providing additional functions to the electronic device.

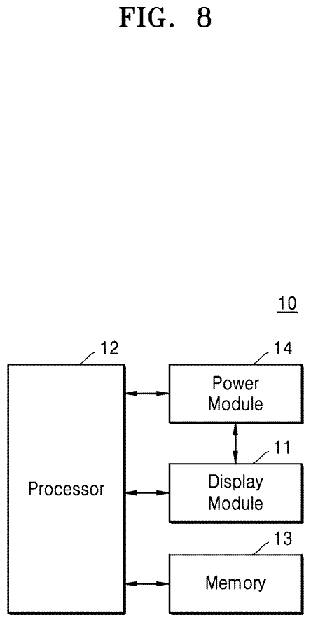

FIG. 8 is a block diagram of an electronic device according to an embodiment. Referring to FIG. 8, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information required for operation of the processor 12 or the display module 11. When the processor 12 executes an application stored in the memory 15, image data signals and/or input control signals are transmitted to the display module 11, and the display module 11 may process received signals to output image information via a display screen.

The power module 14 may include a power supply module such as a power adapter or a battery apparatus, and a power conversion module that converts power supplied by the power supply module to generate power required for operation of the electronic device 10.

At least one of the above-mentioned elements of the electronic device 10 may be included in the display apparatus according to the above-mentioned embodiments. Furthermore, some of the individual modules that are functionally included in a same module may be included in the display apparatus while others may be provided separately from the display apparatus.

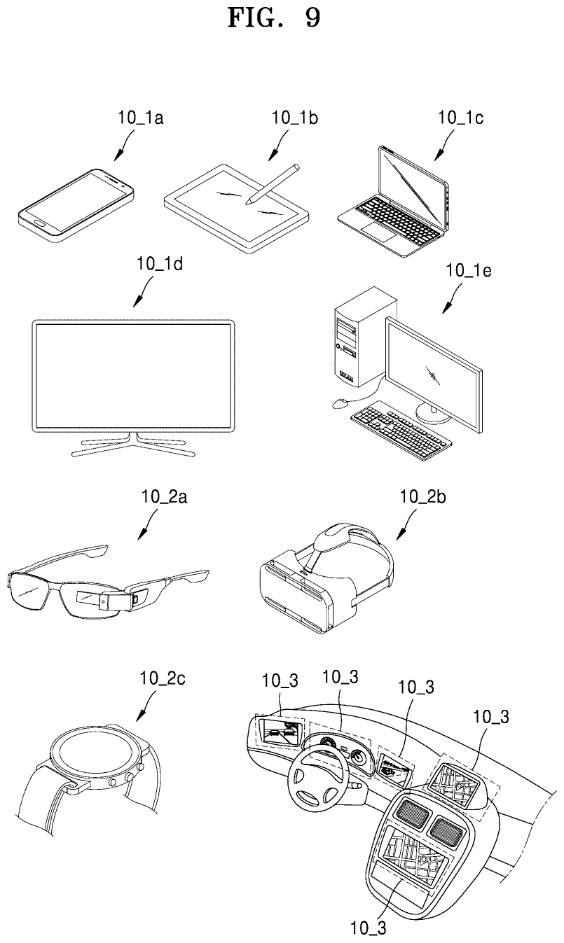

FIG. 9 is a schematic diagram of electronic devices according to several embodiments.

Referring to FIG. 9, various electronic devices with the display apparatus according to embodiments may include electronic devices for displaying images such as smartphones 10_1a, tablets PCs 10_1b, laptops 10_1c, televisions 10_1d, and desktop monitors 10_1e, as well as wearable electronic devices such as smart glasses 10_2a, head-mounted displays 10_2b, and smart watches 10_2c, and automotive electronic devices 10_3 such as center information displays (CIDs) and room mirror displays disposed on an instrument panel, center fascia, or dashboard of a vehicle.

As such, the disclosure has been described with reference to the embodiments shown in the drawings, but this is only exemplary, and those skilled in the art will understand that various modifications and equivalent other embodiments are possible therefrom. Therefore, the true technical scope of the disclosure should be determined by the technical spirit of the appended claims.

An embodiment as described above provides a display apparatus in which planar light incident on an adjacent light-emitting diode is blocked by a barrier. Accordingly, a display apparatus with improved quality (e.g., color gamut) is provided. An embodiment provides a method of manufacturing the display apparatus described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first subpixel electrode and a second subpixel electrode that are spaced apart from each other on the substrate;
a pixel definition layer disposed on the first subpixel electrode and the second subpixel electrode and defining a first opening overlapping the first subpixel electrode and a second opening overlapping the second subpixel electrode; and
a first barrier located on the pixel definition layer between the first opening and the second opening,
wherein the first barrier extends in a first direction, and a length of the first barrier in the first direction is greater than each of a length of the first opening in the first direction and a length of the second opening in the first direction, and
an angle formed between one lateral surface of the first barrier and a top surface of the pixel definition layer is less than 90 degrees.

2. The display apparatus of claim 1, wherein the first barrier includes a light-shielding material.

3. The display apparatus of claim 1, wherein a width of the first barrier in a second direction perpendicular to the first direction is less than a distance between a first edge of the pixel definition layer defining the first opening and a second edge of the pixel definition layer defining the second opening in the second direction.

4. The display apparatus of claim 1, wherein a width of the first barrier in a second direction perpendicular to the first direction is equal to a distance between one edge of the first subpixel electrode and one edge of the second subpixel electrode, which are adjacent to each other in the second direction.

5. The display apparatus of claim 1, wherein the angle formed between one lateral surface of the first barrier and a top surface of the pixel definition layer is greater than 30 degrees.

6. The display apparatus of claim 1, wherein a length of the first opening in the first direction is greater than a width of the first opening in a second direction perpendicular to the first direction.

7. The display apparatus of claim 1, further comprising:
a third subpixel electrode spaced apart from the first subpixel electrode and the second subpixel electrode on the substrate; and
a second barrier disposed on the pixel definition layer and extending in the first direction,
wherein the pixel definition layer defines a third opening overlapping the third subpixel electrode, and
the second barrier is located between the second opening and the third opening.

8. The display apparatus of claim 7, wherein a length of the second barrier in the first direction is greater than a length of the third opening in the first direction.

9. The display apparatus of claim 7, wherein a length of the first barrier in the first direction is greater than a length of the second opening in the first direction.

10. The display apparatus of claim 1, further comprising an encapsulation layer disposed on the pixel definition layer and the first barrier,
wherein a distance from the top surface of the pixel definition layer to a top surface of the encapsulation layer is greater than a distance from a top surface of the pixel definition layer to a top surface of the first barrier.

11. A method of manufacturing a display apparatus, the method comprising:
disposing a first subpixel electrode and a second subpixel electrode on a substrate to be spaced apart from each other;
disposing a pixel definition layer defining a first opening overlapping the first subpixel electrode and a second opening overlapping the second subpixel electrode on the first subpixel electrode and the second subpixel electrode, respectively; and
locating a first barrier on the pixel definition layer between the first opening and the second opening,
wherein the first barrier extends in a first direction, and a length of the first barrier in the first direction is greater than each of a length of the first opening in the first direction and a length of the second opening in the first direction, and
an angle formed between one lateral surface of the first barrier and a top surface of the pixel definition layer is less than 90 degrees.

12. The method of claim 11, wherein the first barrier includes a light-shielding material.

13. The method of claim 11, wherein a width of the first barrier in a second direction perpendicular to the first direction is less than a distance between a first edge of the pixel definition layer defining the first opening and a second edge of the pixel definition layer defining the second opening in the second direction.

14. The method of claim 11, wherein a width of the first barrier in a second direction perpendicular to the first direction is equal to a distance between one edge of the first subpixel electrode and one edge of the second subpixel electrode, which are adjacent to each other in the second direction.

15. The method of claim 11, wherein the angle formed between one lateral surface of the first barrier and a top surface of the pixel definition layer is greater than 30 degrees.

16. The method of claim 11, wherein a length of the first opening in the first direction is greater than a width of the first opening in a second direction perpendicular to the first direction.

17. The method of claim 11, further comprising:
locating a third subpixel electrode to be spaced apart from the first subpixel electrode and the second subpixel electrode on the substrate; and
locating a second barrier extending in the first direction on the pixel definition layer,
wherein the pixel definition layer defines a third opening overlapping the third subpixel electrode, and
the second barrier is located between the second opening and the third opening.

18. The method of claim 17, wherein a length of the second barrier in the first direction is greater than a length of the third opening in the first direction.

19. The method of claim 17, wherein a length of the first barrier in the first direction is greater than a length of the second opening in the first direction.

20. An electronic device comprising a display apparatus, wherein the display apparatus comprises:
a substrate;
a first subpixel electrode and a second subpixel electrode that are spaced apart from each other on the substrate;
a pixel definition layer disposed on the first subpixel electrode and the second subpixel electrode and defining a first opening overlapping the first subpixel electrode and a second opening overlapping the second subpixel electrode; and
a first barrier located on the pixel definition layer between the first opening and the second opening,
wherein the first barrier extends in a first direction, and a length of the first barrier in the first direction is greater than each of a length of the first opening in the first direction and a length of the second opening in the first direction, and
an angle formed between one lateral surface of the first barrier and a top surface of the pixel definition layer is less than 90 degrees.
